(19) United States
(12) Patent Application Publication
(10) Pub. No.: US 2022/0100016 A1
(43) Pub. Date: Mar. 31, 2022

(54) INFORMATION DISPLAY DEVICE USING VARIABLE TRANSMISSIVITY GLASS

(71) Applicants: HYUNDAI MOTOR COMPANY, Seoul (KR); KIA CORPORATION, Seoul (KR)

(72) Inventors: Sung Woo Lee, Gwacheon-si (KR); Han Sol Kang, Yongin-si (KR)

(21) Appl. No.: 17/223,250

(22) Filed: Apr. 6, 2021

(30) Foreign Application Priority Data
Sep. 28, 2020 (KR) 10-2020-0126259

(51) Int. Cl. G02F 1/133; H05K 5/00; G02F 1/1343; G02F 1/1333; E06B 9/24; G09F 9/35

(52) U.S. Cl. CPC G02F 1/13306; H05K 5/0017; G02F 1/13439; E06B 2009/2464; E06B 9/24; G09F 9/35; G02F 1/133365

(57) ABSTRACT

The present disclosure relates to an information display device using a variable transmissivity glass. The information display device includes a controller that divides an entire region of the variable transmissivity glass into a first region and a second region, and adjusts transmissivities of the first region and the second region to be opposite to each other to display information in the first region.

### CROSS REFERENCE TO RELATED APPLICATIONS

This application claims the benefit of priority to Korean Patent Application No. 10-2020-0126259, filed in the Korean Intellectual Property Office on Sep. 28, 2020, the entire contents of which are incorporated herein by reference.

### TECHNICAL FIELD

The present disclosure relates to an information display device using a variable transmissivity glass.

### BACKGROUND

In recent years, instead of mechanical light-shielding apparatuses such as curtains and/or blinds, a transmissivity varying technology that adjusts a transmissivity through electrical control has been in the spotlight. The transmissivity varying technology is a technology that adds a substance performing a light-shielding function to a film or a glass to change the transmissivity as much as a user wants.

The transmissivity varying technology may be classified into electrochromic (EC), suspended particle display (SPD), polymer dispersed liquid crystal (PDLC), and polarized liquid crystal (LC) schemes. The EC scheme changes the transmissivity through electrolysis and bonding of chemical substances, and the SPD, the PDLC, and the LC schemes apply an electric field to both ends of a substance to change a phase of the substance, thereby changing the transmissivity of the light.

### SUMMARY

The present disclosure has been made to solve the above-mentioned problems occurring in the prior art while advantages achieved by the prior art are maintained intact.

An aspect of the present disclosure provides an information display device using a variable transmissivity glass that partially controls a transmissivity of at least a portion of the variable transmissivity glass to display (write) information.

The technical problems to be solved by the present inventive concept are not limited to the aforementioned problems, and any other technical problems not mentioned herein will be clearly understood from the following description by those skilled in the art to which the present disclosure pertains.

According to an aspect of the present disclosure, an information display device includes a variable transmissivity glass, and a controller that divides an entire region of the variable transmissivity glass into a first region and a second region, and adjusts transmissivities of the first region and the second region to be opposite to each other to display information in the first region.

In one implementation, the controller may convert a state of the first region to be a transparent state and convert a state of the second region to be a translucent state or an opaque state.

In one implementation, the controller may convert a state of the first region to be a translucent state or an opaque state and convert a state of the second region to be a transparent state.

In one implementation, the variable transmissivity glass may include transparent first substrate and second substrate, a plurality of first transparent electrodes formed in a first direction on the first substrate, a plurality of second transparent electrodes formed in a second direction on the second substrate, and a liquid crystal disposed between the first transparent electrodes and the second transparent electrodes.

In one implementation, the liquid crystal may be implemented with a polymer macromolecule.

In one implementation, the controller may apply power to at least one first transparent electrode and at least one second transparent electrode overlapping each other in the first region, and not apply the power to at least one first transparent electrode and at least one second transparent electrode overlapping each other in the second region.

In one implementation, the controller may not apply power to at least one first transparent electrode and at least one second transparent electrode overlapping each other in the first region, and apply the power to at least one first transparent electrode and at least one second transparent electrode overlapping each other in the second region.

In one implementation, the first direction may be a vertical direction, and the second direction may be a horizontal direction.

In one implementation, the controller may receive the information from an external device using a communication technology.

In one implementation, the variable transmissivity glass may be installed in a window frame installed to be opened and closed on a sash frame or installed to be included in an outer wall of a building.

### BRIEF DESCRIPTION OF THE FIGURES

The above and other objects, features and advantages of the present disclosure will be more apparent from the following detailed description taken in conjunction with the accompanying drawings:

FIG. 1 is a block diagram illustrating an information display device according to embodiments of the present disclosure;

FIG. 2 is a view for illustrating transmissivity control of a variable transmissivity glass according to embodiments of the present disclosure;

FIG. 3 is an exemplary view illustrating an example of displaying information using a variable transmissivity glass according to an embodiment of the present disclosure;

FIG. 4 is an exemplary view illustrating an example of shielding light using a variable transmissivity glass according to an embodiment of the present disclosure; and

FIG. 5 is an exemplary view illustrating another example of shielding light using a variable transmissivity glass according to an embodiment of the present disclosure.

### DETAILED DESCRIPTION

Hereinafter, some embodiments of the present disclosure will be described in detail with reference to the exemplary drawings. In adding the reference numerals to the components of each drawing, it should be noted that the identical or equivalent component is designated by the identical numeral even when they are displayed on other drawings. Further, in describing the embodiment of the present disclosure, a detailed description of well-known features or functions will be ruled out in order not to unnecessarily obscure the gist of the present disclosure.

In describing the components of the embodiment according to the present disclosure, terms such as first, second, “A”, “B”, (a), (b), and the like may be used. These terms are merely intended to distinguish one component from another component, and the terms do not limit the nature, sequence or order of the constituent components. Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

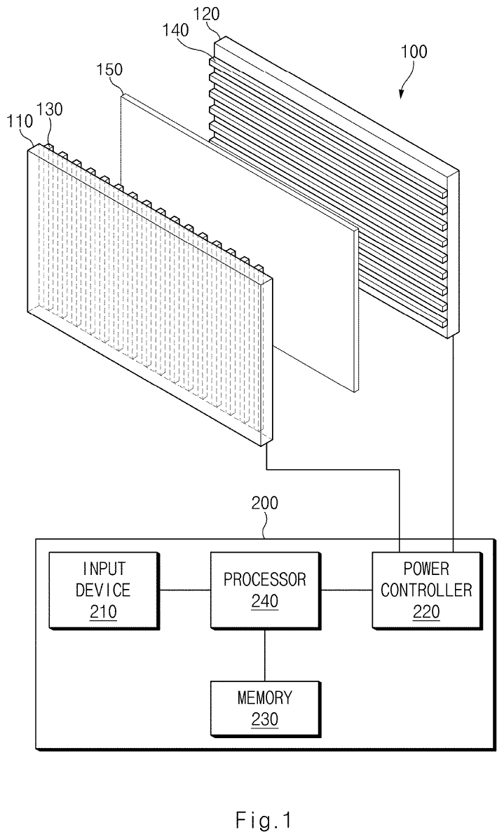

FIG. 1 is a block diagram illustrating an information display device according to embodiments of the present disclosure.

Referring to FIG. 1, an information display device may include a variable transmissivity glass 100 and a controller 200.

The variable transmissivity glass 100 is a liquid crystal glass capable of partial control, which may include a first substrate 110, a second substrate 120, a plurality of first transparent electrodes 130, a plurality of second transparent electrodes 140, and a liquid crystal 150.

The first substrate 110 and the second substrate 120 are arranged to face each other and have transparencies. The first substrate 110 and the second substrate 120 may comprise a glass, a plastic film, or the like.

The plurality of first transparent electrodes 130 may be formed on the first substrate 110 in a first direction. In this connection, the first direction may be a vertical direction. The plurality of first transparent electrodes 130 may be formed in a line shape, and may be arranged on the first substrate 110 at a predetermined spacing.

The plurality of second transparent electrodes 140 may be formed on the second substrate 120 in a second direction. In this connection, the second direction may be a horizontal direction. The plurality of second transparent electrodes 140 may be formed in a line shape like the first transparent electrodes 130, and may be arranged on the second substrate 120 at a predetermined spacing.

The first transparent electrodes 130 and the second transparent electrodes 140 may comprise an indium tin oxide (ITO) and the like.

The liquid crystal 150 is a polymer macromolecule, which may be disposed between the first transparent electrodes 130 and the second transparent electrodes 140. Because a phase of the liquid crystal 150 changes by a potential difference between the first transparent electrodes 130 and the second transparent electrodes 140 respectively disposed on both faces of the liquid crystal 150, a transmissivity of the liquid crystal 150 may be adjusted.

The controller 200 may adjust a transmissivity of at least a portion of the variable transmissivity glass 100 to display information or block transmission of an external light source. The controller 200 may include an input device 210, a power controller 220, a memory 230, and a processor 240.

The input device 210 is for receiving information to be displayed on the variable transmissivity glass 100. The input device 210 may receive information (data) from an external device (e.g., a smart phone, a laptop, and/or a computer, and the like) using a communication technology. As the communication technology, wireless Internet technologies such as a wireless LAN (WLAN)(Wi-Fi) and/or a wireless broadband (Wibro), short-range communication technologies such as a Bluetooth and/or a near field communication (NFC), and/or mobile communication technologies such as an LTE-Advanced and/or an international mobile telecommunication (IMT)-2020, and the like may be applied. In addition, the input device 210 may receive the information from an input device such as a keyboard, a touch pad, and/or a touch screen.

The power controller 220 may be connected to the first transparent electrodes 130 and the second transparent electrodes 140 of the variable transmissivity glass 100, and may supply power to the first transparent electrodes 130 and the second transparent electrodes 140. The power controller 220 may individually and linearly control power (e.g., voltage) supplied to each of the plurality of first transparent electrodes 130. In addition, the power controller 220 may selectively supply common power (e.g., common ground) to at least one of the plurality of second transparent electrodes 140. The power controller 220 may generate a potential difference between the first transparent electrodes 130 and the second transparent electrodes 140 to control the phase of the liquid crystal 150. In other words, the power controller 220 may control the potential difference between the first transparent electrodes 130 and the second transparent electrodes 140 to reverse or convert the phase of the liquid crystal 150.

The memory 230 may be a non-transitory storage medium that stores instructions executed by the processor 240. The memory 230 may be implemented as at least one of storage media (recording media) such as a flash memory, a secure digital card (SD card), a random access memory (RAM), a static random access memory (SRAM), a read only memory (ROM), a programmable read only memory (PROM), an electrically erasable and programmable ROM (EEPROM), an erasable and programmable ROM (EPROM), and/or a register.

The processor 240 may control overall operations of the information display device. Such processor 240 may include at least one of an application specific integrated circuit (ASIC), a digital signal processor (DSP), a programmable logic device (PLD), a field programmable gate array (FPGA), a central processing unit (CPU), a microcontroller, and a microprocessor.

When operating in a light-shielding mode, the processor 240 may adjust the transmissivity of the at least a portion of the variable transmissivity glass 100 to block the transmission of the external light source (e.g., sunlight and/or indoor lighting, and the like).

The processor 240 may receive the information (the data) to be displayed through the input device 210 when operating in a display mode. The processor 240 may divide (allocate) an entire region of the variable transmissivity glass 100 into a first region for displaying the information and a second region serving as a background. When dividing the region, the processor 240 may divide the region in units of pixels. In this connection, the pixel refers to a region where the first transparent electrodes 130 and the second transparent electrodes 140 overlap.

The processor 240 may control transmissivities of the first region and the second region to be opposite (reversed) to each other to display the information. The processor 240 may convert a state of the first region to be a transparent state and convert a state of the second region to be a translucent state or an opaque state. Alternatively, the processor 240 may convert the state of the first region to be the translucent state or the opaque state, and may convert the state of the second region to be the transparent state.

The processor 240 may apply the power to at least one first transparent electrode 130 and at least one second transparent electrode 140 overlapping each other in the first region through the power controller 220 to convert a transparency of the first region to the translucent state or the opaque state. In this connection, the processor 240 may not apply the power to at least one first transparent electrode 130 and at least one second transparent electrode 140 overlapping each other in the second region to maintain a transparency of the second region as the transparent state.

In one example, the processor 240 may not apply the power to the at least one first transparent electrode 130 and the at least one second transparent electrode 140 overlapping each other in the first region to maintain the transparency of the first region as the transparent state. In this connection, the processor 240 may apply the power to the at least one first transparent electrode 130 and the at least one second transparent electrode 140 overlapping each other in the second region through the power controller 220 to convert the transparency of the second region to the translucent state or the opaque state.

As such, the information may be displayed (written) on the variable transmissivity glass 100 by adjusting the transparencies, that is, the transmissivities of the first region and the second region to be reversed. In this connection, the information may be written in a symbol and/or a text form.

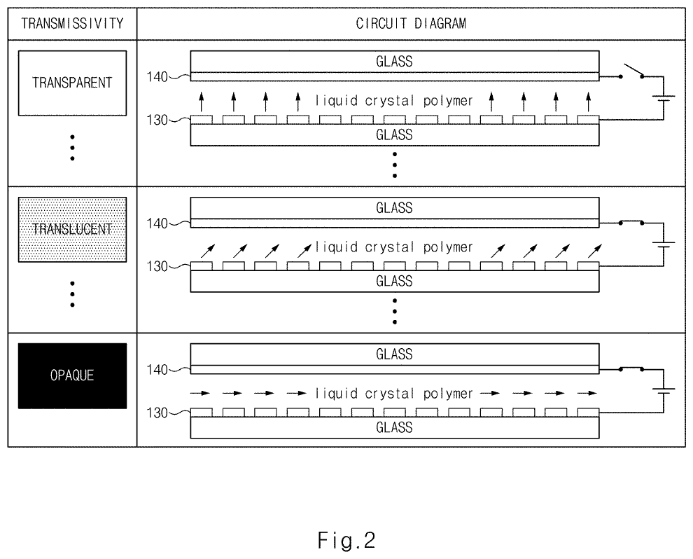

FIG. 2 is a view for illustrating transmissivity control of a variable transmissivity glass according to embodiments of the present disclosure.

Referring to FIG. 2, when the power is not applied to the first transparent electrodes 130 and the second transparent electrodes 140 of the variable transmissivity glass 100, because there is no phase change of the liquid crystal 150 in the variable transmissivity glass 100, the variable transmissivity glass 100 may be maintained in the transparent state.

When the power is applied to the first transparent electrodes 130 and the second transparent electrodes 140 of the variable transmissivity glass 100, a transparency of the variable transmissivity glass 100 may be varied by the phase change of the liquid crystal 150 in the variable transmissivity glass 100. As an electric field applied to the liquid crystal 150 by the power supplied to the first transparent electrodes 130 and the second transparent electrodes 140 increases, the transmissivity of the variable transmissivity glass 100 decreases. Thus, the transparency of the variable transmissivity glass 100 may be varied to the opaque state after going through the translucent state.

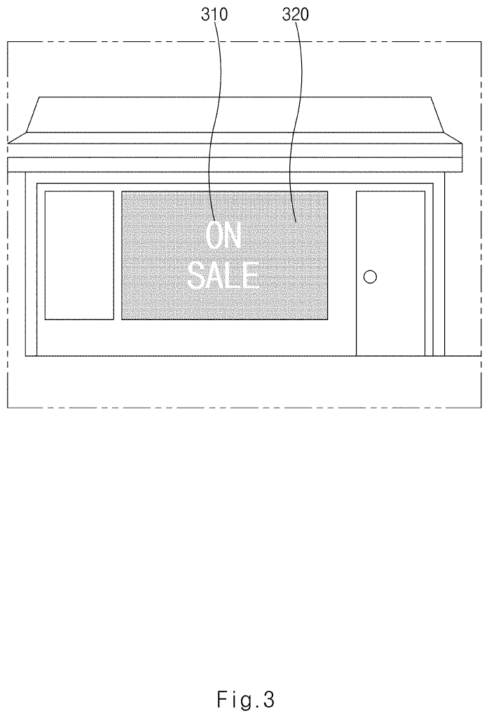

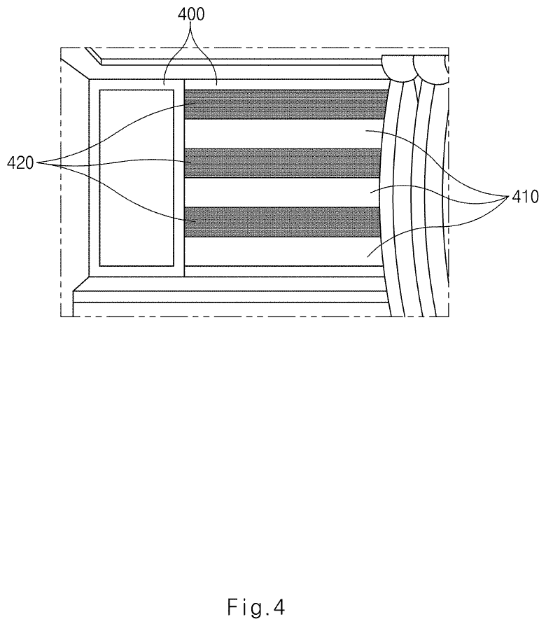

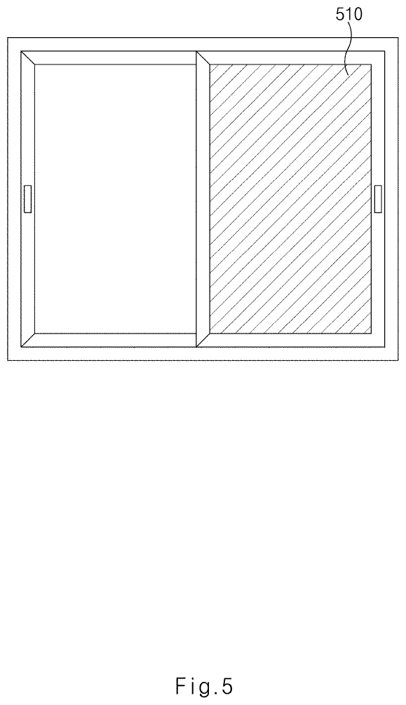

FIG. 3 is an exemplary view illustrating an example of displaying information using a variable transmissivity glass according to an embodiment of the present disclosure, FIG. 4 is an exemplary view illustrating an example of shielding light using a variable transmissivity glass according to an embodiment of the present disclosure, and FIG. 5 is an exemplary view illustrating another example of shielding light using a variable transmissivity glass according to an embodiment of the present disclosure. In the present embodiment, a case in which the variable transmissivity glass 100 is applied to a door and a window will be described as an example.

Referring to FIG. 3, when the variable transmissivity glass 100 is installed in an outer wall of a building and operates in the display mode, the controller 200 may divide the entire region of the variable transmissivity glass 100 into a first region 310 for displaying information and a second region 320 serving as a background. Because the controller 200 adjusts a transmissivity of the first region 310 to process the first region 310 to be in the opaque state, the information such as the symbol or the text may be written. In this connection, the controller 200 maintains the second region 320 in the transparent state to improve visibility of the information displayed on the first region 310. Alternatively, the controller 200 maintains the first region 310 in the transparent state and adjusts the transmissivity of the second region 320 to process the second region 320 to be in the opaque state, the information may be written.

Referring to FIG. 4, when the variable transmissivity glass 100 is installed in a window frame 400 that is opened and closed on a sash frame, and operates in the light-shielding mode, the controller 200 may divide the entire region of the variable transmissivity glass 100 into a first region 410 and a second region 420. The controller 200 may implement a blind shape by adjusting transmissivities of the first region 410 and the second region 420 to be different from each other. For example, the controller 200 may process the first region 410 to be in the transparent state and may process the second region 420 to be in the translucent state or the opaque state.

Referring to FIG. 5, when the variable transmissivity glass 100 is applied to a window and operates in the light-shielding mode, the controller 200 may adjust a transmissivity of an entire region 510 of the variable transmissivity glass 100. The controller 200 may adjust the transmissivity of the variable transmissivity glass 100 to adjust an amount of light transmitted through the window.

As described above, because the external light incident on at least the portion of the variable transmissivity glass 100 is transmitted or blocked through the partial control, the information display function and the light-shielding function may be provided.

The description above is merely illustrative of the technical idea of the present disclosure, and various modifications and changes may be made by those skilled in the art without departing from the essential characteristics of the present disclosure. Therefore, the embodiments disclosed in the present disclosure are not intended to limit the technical idea of the present disclosure but to illustrate the present disclosure, and the scope of the technical idea of the present disclosure is not limited by the embodiments. The scope of the present disclosure should be construed as being covered by the scope of the appended claims, and all technical ideas falling within the scope of the claims should be construed as being included in the scope of the present disclosure.

According to the present disclosure, because the information is displayed by partially controlling the transmissivity of at least the portion of the variable transmissivity glass, the information may be displayed without applying a separate display device.

In addition, according to the present disclosure, the variable transmissivity glass is applied to the building and/or a vehicle to deliver information to unspecified individuals located indoors and/or outdoors or provide aesthetic effects, thereby promoting convenience and safety of the user.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

1. An information display device comprising:
a variable transmissivity glass; and
a controller configured to divide an entire region of the variable transmissivity glass into a first region and a second region, and to adjust transmissivities of the first region and the second region to be opposite to each other to display information in the first region.

2. The information display device of claim 1, wherein the controller is configured to convert a state of the first region to a transparent state and to convert a state of the second region to a translucent state or an opaque state.

3. The information display device of claim 1, wherein the controller is configured to convert a state of the first region to a translucent state or an opaque state and to convert a state of the second region to a transparent state.

4. The information display device of claim 1, wherein the variable transmissivity glass includes:
a transparent first substrate and a transparent second substrate;
a plurality of first transparent electrodes formed in a first direction on the transparent first substrate;
a plurality of second transparent electrodes formed in a second direction on the transparent second substrate; and
a liquid crystal disposed between the plurality of first transparent electrodes and the plurality of second transparent electrodes.

5. The information display device of claim 4, wherein the liquid crystal comprises a polymer macromolecule.

6. The information display device of claim 4, wherein the controller is configured to:
apply power to at least one of the plurality of first transparent electrodes and at least one of the plurality of second transparent electrodes overlapping each other in the first region; and
not apply the power to at least one of the plurality of first transparent electrodes and at least one of the plurality of second transparent electrodes overlapping each other in the second region.

7. The information display device of claim 4, wherein the controller is configured to:
not apply power to at least one of the plurality of first transparent electrodes and at least one of the plurality of second transparent electrodes overlapping each other in the first region; and
apply the power to at least one of the plurality of first transparent electrodes and at least one of the plurality of second transparent electrodes overlapping each other in the second region.

8. The information display device of claim 4, wherein the first direction is a vertical direction and the second direction is a horizontal direction.

9. The information display device of claim 1, wherein the controller is configured to receive the information from an external device using a communication technology.

10. The information display device of claim 1, wherein the variable transmissivity glass is installed in a window frame configured to be opened and closed on a sash frame, or installed in an outer wall of a building.
